(19) United States
(12) Patent Application Publication
(10) Pub. No.: US 2026/0142500 A1
(43) Pub. Date: May 21, 2026

(54) METHOD FOR AUTOMATICALLY MANAGING OUTPUT POWER OF A RADIO FREQUENCY (RF) TRANSMISSION SYSTEM

(71) Applicant: ROCKWELL COLLINS, INC., Cedar Rapids, IA (US)

(72) Inventors: Wayne TATTERSHALL, Cedar Rapids, IA (US); Mark B. JORGENSON, Kanata (CA); Scott K. HASSON, Richmond (CA); Andrew KAMEL, Stittsville (CA); Mohamed Amine KHALF, Gatineau (CA); Joseph F. JIACINTO, Mount Vernon, IA (US)

(73) Assignee: ROCKWELL COLLINS, INC., Cedar Rapids, IA (US)

(21) Appl. No.: 18/953,669

(22) Filed: Nov. 20, 2024

(51) Int. Cl. H02J 50/20; H03F 3/24

(52) U.S. Cl. CPC H02J 50/20; H03F 3/245; H03F 2200/451

(57) ABSTRACT

A system and method for managing and controlling a transmit power of a transmitter of a RF transmission system are disclosed. When the transmitter operates from a constrained supply like a generator or battery, power draw may limit the output that can be supported by the transmitter or result in a shutdown of the entire system. The system includes a plurality of detection and measurement circuitries to detect parameters relative to the transmitter load quality, transmitter temperatures, input waveform quality, and input power source to ensure an output power of the transmitter to stay below an allowed input power. The system and method provide a reliable transmitter that is not subject to power overloads and shutdowns caused by a circuit malfunction.

### FIELD OF THE INVENTION

The present invention relates to methods for automatically controlling input power and output power of a RF (Radio Frequency) transmission system based on direct measurements of input power draw or an estimation of input power draw based on measurements made in the power amplifier system. The present invention is particularly unique when there is a need or desire to limit the power consumed by the transmitter, including its power amplifier.

### BACKGROUND OF THE INVENTION

RF systems often use power amplifiers to take a low power input signal and transform that input signal into a much higher power output signal. This is useful for many applications, including for the transmission of RF signals over long distances where higher power signals are required to overcome propagation losses. Power amplifier systems often include methods to control the output power of the signal based on a user input, a measured output power, a power reflected back to the transmitter by the load or antenna, or in response to fault conditions within the power amplifier or its ancillary equipment. High power transmitters often draw significant power from their power source, whether that is part of an electrical grid, a battery, a dedicated generator, or other power sources. When the transmitter must operate over a range of conditions such as a range of operating frequencies or a range of temperatures, the efficiency of the power amplifier will vary depending on the specific set of conditions. The maximum RF output power that is achievable with a limited external power source will be dependent upon the efficiency of the power amplifier under the specific set of conditions. When multiple input signals are used, the characteristics of the input signals becomes another factor which serves to limit the available output power of the transmitter.

### SUMMARY OF THE INVENTION

The present disclosure is directed, in some embodiments, to a system for managing the transmission power of a RF (Radio Frequency) transmission system including a transmitter that further includes at least one power amplifier. The system includes a plurality of detection and measurement circuitries coupled to the transmitter to determine parameters relative to the transmitter, in which the parameters comprise measurements within the transmitter, a quality measurement of an input power draw of the transmitter from the external power supply, and a quantity measurement of the input power available to the transmitter from the external power supply. The system further includes a power management controller configured to receive and process the parameters detected by the plurality of detection and measurement circuitries and to manage and control an output power of the transmitter based the parameters. The power management controller is configured to determine an available input power that the transmitter is allowed to draw based on the measurements of the detection and measurement circuitries, wherein the available input power is either fixed or configurable, dynamically determine an input power draw of the transmitter from the power supply, and control elements of the transmitter to keep the output power within a desired range while ensuring that the input power draw of the transmitter does not exceed the available power from the external power supply.

The system further includes an input device for receiving user inputs and a memory for storing at least one available power threshold for the transmitter. The user inputs include at least one adjustment of the available power that is supplied to the transmitter and the output power of the transmitter. The power management controller controls the element of the transmitter to ensuring the input power the transmitter draws does not exceed the available power based on at least one available power threshold stored in the memory.

The power management controller according to the disclosed embodiments determines the available input power that is available to be supplied to the transmitter based on at least one of: reading the available power threshold stored in the memory that indicates the available power, detecting an analog signal that is mapped to indicate the available power, and detecting a digital signal that indicates the available power. The power management controller is further configured to dynamically determine the input power draw of the transmitter using the measurements within the transmitter, or based on transmitter characterization to determine the input power draw from the power supply, to reduce the output power of the transmitter, to adapt at least one of a linearity and an efficiency characteristics of the at least one power amplifier, or to change at least one of a bias voltage and the supply voltage of the at least one power amplifier to effect at least one of the linearity and the efficiency of the at least one power amplifier, so that the output power is kept within the desired range while ensuring that the input power draw does not exceed the available power.

Further, the power management controller of the disclosed embodiments may reduce the output power of the transmitter by at least one or more the followings: reducing a level of a signal input to the at least one power amplifier, attenuating the signal within the at least one power amplifier, reducing a gain of the at least one power amplifier, and reducing a supply voltage of the at least one amplifier. The system of claim 1, wherein the power management control is further configured to control the elements of the transmitter to keep the output power within the desired range while ensuring that the input power draw does not exceed the available power.

In yet another embodiment, the present disclosure is directed to a system for managing the transmission power of a RF (Radio Frequency) transmission system including a transmitter for transmitting multiple input signals after being amplified by at least one power amplifier. The system includes a plurality of detection and measurement circuitries coupled to the transmitter to determine parameters relative to the transmitter, in which the parameters comprise measurements within the transmitter, a quality measurement of an input power draw of the transmitter from the external power supply, and a quantity measurement of the input power available to the transmitter from the external power supply, and a power management controller configured to process the parameters detected by the plurality of detection and measurement circuitries and to manage and control the transmit power. The power management controller is configured to determine an available input power that the transmitter is allowed to draw based on the measurements of the detection and measurement circuitries, wherein the available input power is either fixed or configurable, dynamically determine the input power draw for the transmitter based on the measurements within the transmitter and power levels of the multiple signals, and control elements of the transmitter to keep the output power of the transmitter within a desired range while ensuring that the input power draw does not exceed the available power.

In the disclosed embodiments, the power management controller is configured to control the elements of the transmitter to keep the output power within the desired range while ensuring that the input power draw does not exceed the available power by adapting at least one of a linearity and efficiency characteristics of the at least one power amplifier. The power management controller is further configured to change at least one of a bias voltage and a supply voltage of the at least one power amplifier to affect the at least one of the linearity and efficiency of the at least one power amplifier.

The system further includes a memory for storing a priority list of the multiple input signals, and the power management controller is configured to determine linearity requirements of the at least one power amplifier based on the priority list of the multiple input signals and a measurement of a quality of at least one signal of the multiple input signals, and to adjust the relative transmit power of the multiple input signals based on the parameters determined by measurement of the at least one quality of the at least one input signals.

In yet another embodiment, the present disclosure is directed to a method for managing and controlling a transmit power of an RF transmission system including a transmitter to transmit at least one input signal after amplified by at least one power amplifier. The method comprises measuring various parameters relative to the transmitter, in which the parameters comprise measurements within the transmitter, a quality measurement of an input power draw of the transmitter from the external power supply, and a quantity measurement of the input power available to the transmitter from the external power supply, determining an available input power that the transmitter is allowed to draw from the external power supply based on the measurements of the detection and measurement circuitries, wherein the available input power is either fixed or configurable, dynamically determining the input power draw for the transmitter based on the measurements within the transmitter, and controlling elements of the transmitter to keep the output power of the transmitter within a desired range while ensuring that the input power draw does not exceed the available power.

The method further comprises reducing the output power of the transmitter by at least one or more of the following: reducing the power level of the at least one input signal, attenuating the input signal within the at least one power amplifier, reducing a gain of the at least one power amplifier, and reducing a supply voltage of the at least one power amplifier.

The method further comprises controlling the elements of the transmitter to keep output power within the desired range while ensuring that the input power draw does not exceed the available power by adapting at least one of a linearity and efficiency characteristics of the at least one power amplifier.

### BRIEF DESCRIPTION OF FIGURES

The features of the disclosure believed to be novel and the elements characteristic of the invention are set forth with particularity in the appended claims. The figures are for illustration purposes only and are not drawn to scale. The disclosure itself, however, both as to organization and method of operation, can best be understood by reference to the description of the preferred embodiment(s) which follows, taken in conjunction with the accompanying drawings in which:

FIG. 1 illustrates a schematic diagram of a RF transmission system.

FIG. 2 depicts a power management and control system for automatically managing an output power from an input power side in accordance with the disclosed embodiments.

FIG. 3 illustrates different scenarios of using a power management controller to control an output power of a transmission system in accordance with the disclosed embodiments.

FIG. 4 illustrates an embodiment for using a power management controller to control an output power of a RF transmission system that transmits a plurality of individual signals in accordance with the disclosed embodiments.

FIG. 5 depicts a flowchart of a method for managing output power of a RF transmission system using power management and control system in accordance with the disclosed embodiments.

### DETAILED DESCRIPTION OF THE INVENTION

The embodiments of the present disclosure can comprise, consist of, and consist essentially of the features and/or steps described herein, as well as any of the additional or optional ingredients, components, steps, or limitations described herein or would otherwise be appreciated by one of skill in the art.

As used herein, a letter following a reference numeral is intended to reference an embodiment of the feature or element that may be similar, but not necessarily identical, to a previously described element or feature bearing the same reference numeral, such as 1, 1a, or 1b. Such shorthand notations are used for purposes of convenience only, and should not be construed to limit the inventive concepts disclosed herein in any way unless expressly stated to the contrary.

Moreover, unless expressly stated to the contrary, “or” refers to an inclusive or and not to an exclusive or. For example, a condition A or B is satisfied by anyone of the following: A is true (or present) and B is false (or not present), A is false (or not present) and B is true (or present), and both A and B are true (or present).

In addition, use of the “a” or “an” are employed to describe elements and components of embodiments of the instant disclosed concepts. This is done merely for convenience and to give a general sense of the disclosed concepts, and “a” and “an” are intended to include one or at least one and the singular also includes plural unless it is obvious that it is meant otherwise. It will be further understood that the terms “comprises” or “comprising,” when used in this specification, specify the presence of stated features, integers, steps, operations, elements, or components, but do not preclude the presence or addition of one or more other features, integers, steps, operations, elements, components, and/or groups thereof.

As used herein, any reference to “one embodiment,” “alternative embodiments,” or “some embodiments” means that particular element, feature, structure, or characteristic described in connection with the embodiment is included in at least one embodiment of the inventive concepts disclosed herein. The appearances of the phrase “in some embodiments” in various places in the specification are not necessarily all referring to the same embodiment, and embodiments of the disclosed concepts disclosed may include one or more of the features expressly described or inherently present herein, or any combination or sub-combination of two or more such features, along with any other features that may not necessarily be expressly described or inherently present in the instant disclosure.

The disclosed embodiments may be described with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

The flowchart and block diagrams in the figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams or flowchart illustration, and combinations of blocks in the block diagrams or flowchart illustration, can be implemented by special purpose hardware-based systems that perform the specified functions or acts, or combinations of special purpose hardware and computer instructions.

Inventive concepts may be implemented as a computer process, a computing system or as an article of manufacture such as a computer program product of computer readable media. The computer program product may be a computer storage medium readable by a computer system and encoding computer program instructions for executing a computer process. When accessed, the instructions cause a processor to enable other components to perform the functions disclosed below.

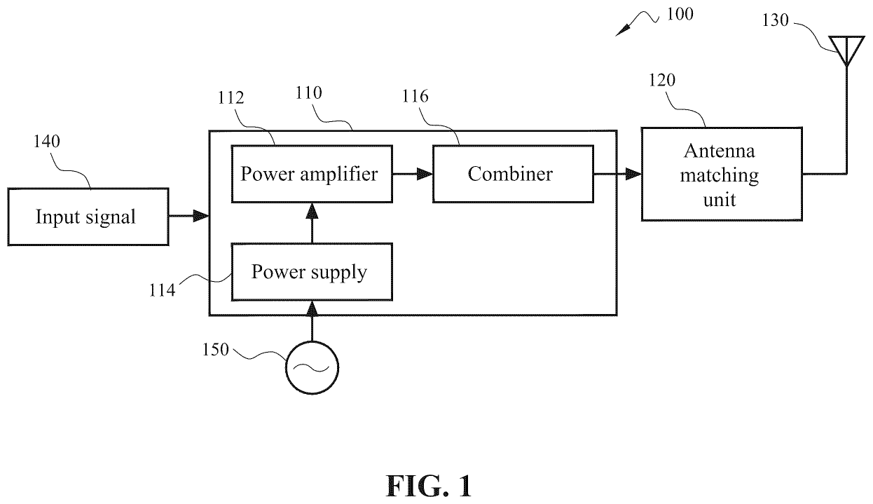

FIG. 1 illustrates a basic RF transmission system 100 or a transmission system 100 that includes a power amplifier system 110, an antenna matching unit 120, and an antenna 130. Power amplifier system 110 includes at least one power amplifier 112 and at least one power supply unit 114 and may include at least one combiner 116. A signal 140 is input to power amplifier 112 that increases the power of signal 140 and outputs an amplified output signal 118. The at least one power amplifier 112 receives power from the at least one power supply unit 114 and the at least one power supply unit 114 is connected to a source of electrical power 150 that can be a power grid or a generator or a battery or other supply of electrical power. In some cases, the at least one power amplifier 112 and the at least one power supply unit 114 may be combined in a single device. In cases where a wide range of frequencies is used and where the load or antenna impedance does not remain nearly constant, an antenna tuner or antenna matching unit 120 will be employed to match the impedance of the transmitter output and the load or antenna.

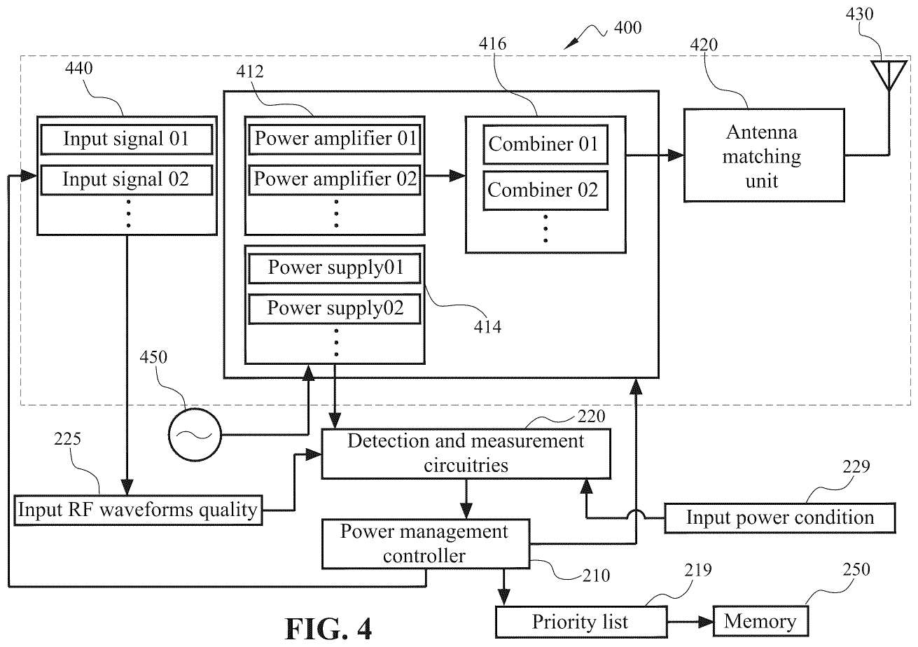

In FIG. 1, only a single input signal is shown. However, in some other embodiments, transmission system 100 may receive multiple input signals, such as in an Electronic Warfare (EW) transmission system (will be described later in FIG. 4.) In these embodiments, the at least one power amplifiers 112 amplifies the received multiple input signals. Multiple combiners are used to combine outputs from the multiple power amplifiers into a single signal for output to the load or antenna 130.

When a transmitted power source is limited, for example, the power comes from a constant supply like a generator, a battery, or a grid power circuit, the RF transmission systems normally are designed specifically to operate with a power draw that remains within the capacity of the supply. RF transmission systems typically uses an automatic level control (ALC) that keeps the output power below the maximum rated power. The maximum rated power is usually determined based on the worst case normal operating conditions and the power amplifier limits the output power to that maximum rated power regardless of whether the amplifier could actually provide higher than rated power under a specific set of conditions. For example, a 1 kW amplifier will typically provide 1 kW across the entire band of frequencies that it supports but it may draw varying amounts of power from the external supply to generate that 1 kW signal as frequency changes. If it requires 6 kW to output a 1 kW signal at the high end of the band and 3 kW at the low end of the band, it will exceed the capacity of a 5 kW generator for the upper frequencies and will typically trip the breaker.

In this situation, power draw may limit the output that can be supported or result in a shutdown of the entire system. Where the transmitter supports a variable number of signals at different frequencies and/or amplitudes and/or duty cycles, the supportable power for each individual signal may have to be adjusted based on the number of signals. Also, a value of an input power to achieve a particular output power may change with frequency.

Accordingly, the disclosed embodiments aim to control the output power to stay below an allowed input power so as to simplify a power control loop and provide a reliable transmitter that is not subject to power overloads and shutdowns arising from a circuit breaker or fuse opening.

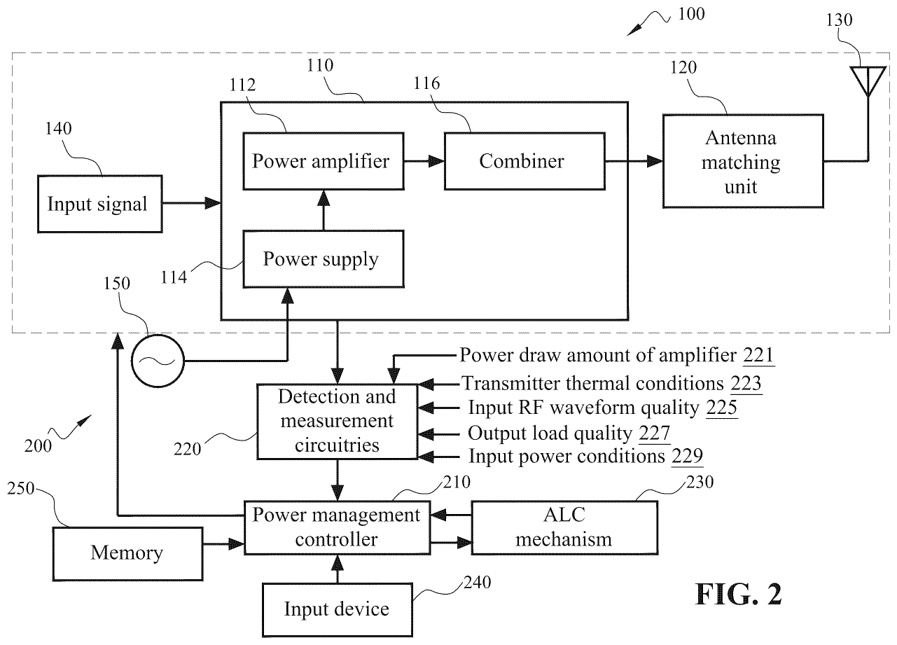

FIG. 2 depicts a power management and control system 200 for automatically managing an output power from an input power side in accordance with the disclosed embodiments.

System 200 is a power management and controlling system that includes a power management controller 210 to monitor and control transmission system 100, and a number of detection and measurement circuitries 220 for detecting and measuring various parameters relative to transmission system 100. In FIG. 2, power management controller 210 and detection and measurement circuitries 220 are separate components from transmission system 100. However, power management controller 210 and detection and measurement circuitries 220 may also be part of transmission system 100. There is no limit in this regard.

In accordance with the disclosed embodiments, system 200 uses a direct measurement of an input power (provided by power supply 114) from an external supply, i.e., external supply 150, or an estimate of the input power from the external supply, extrapolated from measurements made within transmission system 100, as an input to a power management controller 210. Power management controller 210 is capable of adapting the output RF power based on the actual or inferred power pulled from the external supply. In the simplest case, with a fixed gain power amplifier, the power management and control system 200 is capable of reducing an amplitude or a power of the input signal 140, thereby reducing a power output from the power amplifier 112, to prevent the power amplifier unit 110 from drawing more than a configured amount of power from external supply 150. External power supply 150 is communicatively coupled to the transmitter. The configured amount of the power draw from the external supply 150 may be a fixed amount, or a configurable amount based on measurements relative to transmission system 100, the direct measurement of the input power or the estimated input power, and/or the measurements made within transmission system 100. In other embodiments, the configured amount of the power draw may be determined from a user input received through input device 240 or a message received from external power source 150.

Power management and control system 200 may include other more traditional control inputs based on RF output power. For example, the RF output power could be adjusted (reduced) by a conventional ALC mechanism 230 designed to keep the peak output RF power below a specified value when the input power draw for transmission system 100 from external power supply 150 was below the configured value. Together with the operation of the ALC mechanism 230 and other mechanisms intended to protect against various conditions unrelated to the power draw from the external supply, system 200 may adjust the output RF power based on the power draw from the external supply in combination with those mechanisms. ALC mechanism 230 may be a part of transmission system 100, or a separate mechanism that can be used in conjunction with system 200, or a part of system 200. There is not limits in this regard.

Some of the mechanisms used in system 200 may include a number of detection and measurement circuitries, collectively named as detection and measurement circuitries 220 to monitor and detect the condition of transmission system 100. Detection and measurement circuitries 220 measure a variety of parameters relative to transmission system 100. For example, these parameters may include a power draw amount 221 of transmission system 100 (i.e. for power amplifier 112) from external supply 150, transmitter thermal conditions 223 of transmission system 100 that include an ambient temperature, chassis temperature, and transmitter temperature; the characterization of input RF waveform 225, such as its envelope, phase, duty cycle, frequency, amplitude; the output load quality 227 or match to the output load (i.e., antenna 130) including a forward power, a reverse power, or a VSWR; and the power quality 229 of power supply 214, including an amperage, a voltage, and a power factor of the available power. The detected results of these circuitries are sent to a power management controller 210 for further processing.

Power management controller 210 is a core element of system 200 that processes all data detected and sent from detection and measurement circuitries 220 to manage and control how much power can be drawn from a power source that has a limited power. Power management controller 210 may be a digital processing device, or an analog circuitry, or a processor without limits. Based on these measurements received from detection and measurement circuitries 220, power management controller 210 adjusts the output power to stay below an allowed input power when the available power 220 is limited, to ensure that transmission system 100 is not subject to power overloads or shutdown caused by a circuit break or an opened fuse.

Further, detection and measurement circuitries 220 monitor dynamically power supply 114 regarding the availability, condition, and capability of its input power. As known, a power supplied from power supply 114 to power amplifier 112 will be ultimately converted to a higher RF power level required to be input to antenna 130. External supply 150 that supplies power to power supply 114 can be direct current (DC), alternating current (AC), battery, line, or remotely generator (vehicular, solar, etc.). Detection and measurement circuitries 220 measure a power draw amount of the power amplifier 221, a quality of the input power of power supply 229, such as the amperage, voltage, and power factor of the input power, and sends the input power condition measurements 229 to power management controller 210 for processing. Based on these measurements, power management controller 210 may dynamically characterize the available power source and provides a control function to steer power amplifier 112 biasing to optimal classes of operation, given dynamically changing or limited input power options. The amplifier biasing can be tuned for linearity, power added efficiency, duty cycle, average output power, peak output power.

This feature is particularly advantageous because a transmitter that nominally draws, for example, 5 kW of system source power in a typical transmission system, would not be able to function or transmit with a power source less than 5 kW. When the power source is less than 5 kW, the disclosed embodiments should be able to control and enable transmitter 250 to operate with a power source less than 5 kW by reducing the RF output power to limit a drawable power from the power source 150, and intelligently controlling power amplifier 112 to provide a reduced transmit power at the maximum level possible at the reduced line power. On the contrary, in a conventional RF transmission system, an insufficient input power source would cause the amplifier to completely shutdown.

There are many ways to control the output power to stay below the allowed input power when the power supplied from power source is limited. For example, power management controller 210 may reduce the amplitude of input signal 140, reduce a power level of input signal 140, or reduce the gain of power amplifier 112, and so on, based on various measurements received from detection and measurement circuitries. In accordance with the disclosed embodiments, power management controller 210 may reduce the output power of the transmitter by at least one or more the followings: reducing a signal level of input signal 140 to power amplifier 112, attenuating input signal 140 within power amplifier 112, reducing a gain of power amplifier 112, and reducing a supply voltage of power amplifier. Power management controller 210 may further control elements of the transmitter to keep the output power within a desired range while ensuring that the input power draw does not exceed the available power of external supply 150 by adapting at least one of a linearity and an efficiency characteristics of power amplifier 112. In these embodiments, power management controller 210 may change at least one of a bias voltage and a supply voltage of power amplifier 112 to affect at least one of the linearity and the efficiency of power amplifier 112. In some embodiments, power management controller 210 may dynamically determines the input power draw of the transmission system 100 using the measurements within transmission system 100, or based on transmitter characterization to determine the input power draw from the power supply.

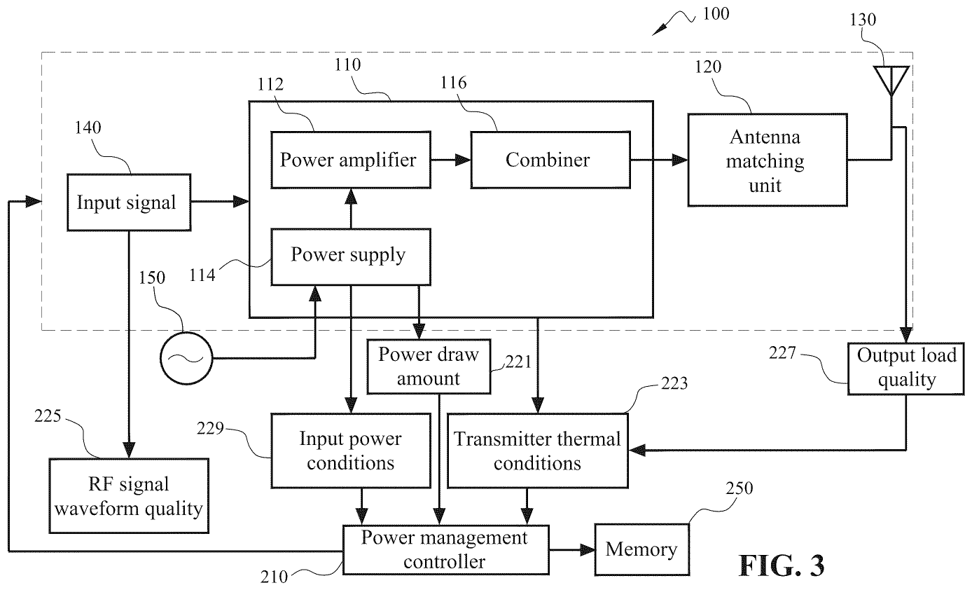

The following FIGS. 3-4 will describe different scenarios that power management controller 210 manages the RF output power based on various measured parameters.

FIG. 3 illustrates different scenarios of power management controller 210 for controlling an output power of transmission system 100 by referring to measured parameters received from detection and measurement circuitries. A first scenario is to control the output power by referring to VSWR (Voltage Standing Wave Ratio.) VSWR is a ratio of a maximum voltage to a minimum voltage on a transmission line. For a radio to deliver to an antenna (transmitting or receiving), an impedance of the radio and transmission line needs to be well matched to an impedance of the antenna. If they are not matched, some of the output power will be reflected back to form the reflected power.

As described above, most transmitters have ALC (Automatic Level Control) functions that can manage a transmit power, based on measuring output signals, to remain below a threshold level that may damage the amplifier, regardless of the load that the transmitter is connected to. When the input power (current) is the limiting factor, as is the case when the output of a transmitter is constrained by the amount of power (or current) that it is allowed to draw from a power source, the ALC based approach is not optimum. Therefore, the disclosed embodiments aim to further limit the output power of transmission system 100 based on a measurement of the input power in addition to the measurements of the output power and the reflected power. This approach would work correctly, independently of varying efficiency of the amplifier with VSWR or across frequency.

In the first scenario, power management controller 210 would determine a power management protocol by considering measurements such as output load quality 227 and input power condition 229. As described above, the input power condition measurements 229 may include measurements of the amperage, the voltage, and the power factor of the available power 220. The output load quality 227 may include measurements of one or more of an amplitude or power of forward and reverse signals, a measurement of amplitude or power, phase/time delay of the transmitter signal power reﬂected by antenna 130. The output load quality measurements 227 can also be used to calculate a VSWR. Therefore, by comparing the output load quality measurements and the input power condition measurements 229, power management controller 210 may adjust and reduce a transmit power of transmission system 100 based on the calculated VSWR and the available input power at power supply 114. Effectively the more conventional ALC mechanism will act to keep output power below a desired maximum output level and power management and control system 200 of the disclosed embodiments will act in parallel to keep the power draw from the supply below a specified level when the power draw is not sufficiently limited by the action of the ALC mechanism. That is, power management and control system 200 may be used in conjunction with the ALC mechanism, element 230 shown in FIG. 2, to control the elements of the transmitter to keep the output power within the desired range while ensuring that the input power draw does not exceed the available input power.

Alternatively, power management controller 210 may preset and stores a VSWR threshold in a memory 250. If the load impedance fails to match the output impedance of transmission system 100 and the calculated VSWR exceeds the VSWR threshold, power management controller 210 may reduce the transmit power to protect transmission system 100 from damage. Other than using the preset VSWR threshold as a trigger to reduce the transmit power, power management controller 210 may further reduce the transmit power only when a predetermined specific high VSWR is detected and/or the current or power supplied from power supply 113 exceeds to a preset limit. By presetting the VSWR threshold, the specific high VSWR, and the power limit, the power management controller 210 may automatically reduce the transmit power whenever the above preset values are reached.

In addition to the VSWR threshold, memory 250 may also store at least one available power threshold for transmission system 100 so that the power management controller controls the elements of transmission system 100 to ensure that the input power draw of transmission system 100 does not exceed the available power based on at least one available power threshold stored in memory.

A second scenario illustrated in FIG. 3 is that power management controller 210 may control the output power (i.e., the transmitting power) of transmission system 100 by using an adaptive amplifier biasing power limiting manner.

In the second scenario, detection and measurement circuitries 220 (shown in FIG. 2) monitor dynamically power supply 114 regarding the availability, condition, and capability of its input power. Detection and measurement circuitries 220 measure a quality of the input power of power supply 114, such as the amperage, voltage, and power factor of the input power, and sends the input power condition measurements 229 to power management controller 210 for processing. Based on these measurements, power management controller 210 may determine the amount of the input power drawn by transmission system 100 and dynamically characterize the available power source and provides a control function to steer power amplifier 112 biasing to optimal classes of operation, given dynamically changing or limited input power options. By detecting and determining input signal characteristics the waveforms can be classified as a linear modulated signal (one that modulates amplitude or amplitude and phase) or a non-linear or constant envelope signal (one that modulates phase alone) the bias points and supply voltage can be changed to optimize the transmission system. When a constant envelope is detected the supply voltage and bias could be reduced to the minimum value needed to achieve transmitted power while maximizing system efficiency. When a linear modulated signal is detected after the bias and supply voltages are then raised to support the linearity based on the specific signals peak to average ratio. Whereas without these dynamic changes the efficiency enhancement to the system power efficiency would not be achievable. When combined with controlling output power based on input power limitations ensures continuous maximum system efficiency.

As described, this feature is particularly advantageous when the power source is less than 5 kW (as an example) that is what the transmitter would nominally draws. Using the second scenario, power management controller 210 is able to control and enable transmission system 100 to operate with a power source less than 5 kW by reducing the RF output power to limit a drawable power from the power source 150, and intelligently controlling power amplifier 112 to provide a reduced transmit power at the maximum level possible at the reduced line power.

A third scenario illustrated in FIG. 3 is that the power management controller 210 may manage the transmitting or output power based on transmitter thermal condition measurements 223 and the input power condition measurements 229.

Detection and measurement circuitries 220 sense and measure temperatures of various components in transmission system 100. For example, detection and measurement circuitries 220 may measure a temperature of an ambient installation environment, a temperature of a chassis enclosure, and a temperature of transmitter final stage electronics. As temperature of the transmission system 100 increases, the power transmission capability of power amplifier 112 will be reduced. Therefore, by means of these thermal characterization (i.e., efficiency) and the input power draw, power management controller 210 is able to determine thermal impacts on transmission system 100. The thermal characterization of operating efficiency can determine a maximum amount of the input power draw from external supply 150 to maintain safe thermal operating ranges. Therefore, by analyzing the thermal condition measurements 223 and the input power condition measurements 229, power management controller 210 provide an ability to reduce transmission power in order to reduce the power demand of external supply 150, to protect transmission system 100 from thermal overload, and extend the operation period of power amplifier 112 in higher thermal conditions.

In some alternative embodiments, power management controller 210 may calculate a power transmission capability value, based on the thermal condition measurements 208, as a function of these temperatures, and obtain a thermal power transmission capability profile based on the thermal specifications of transmission system 100. System characterization of operating efficiency can determine the maximum power draw of power supply 114 to maintain safe thermal operating ranges. With the thermal power transmission capability profile, power management controller 210 may automatically reduce transmission power in order to limit the power demand of power supply 114, to protect the transmission system from thermal overload and to maintain the calculated power transmission capability limit by referring to input power condition measurements 229.

Power management and control system 200 in accordance with the disclosed embodiments may further control and manage the transmit power by maintaining the transmit capabilities of an RF transmission system that can transmit signals at various power levels and frequencies dynamically on an as-needed basis. One example of this RF transmission system is an Electronic Warfare (EW) System. Other examples may also include cellular base station and high-power transmitter on ships that combines multiple signals into a single power amplifier system that feeds a single antenna. The transmitter in these systems supports multiple independent signals. When the power source is constrained, the power for transmitting these individual signals may need to be reduced.

FIG. 4 illustrates an embodiment for using power management controller 210 to control an output power of a RF transmission system 400 that transmits a plurality of individual signals in accordance with the disclosed embodiments.

RF transmission system 400 is used to receive or generate multiple input signals 440 and transmit the multiple input signals, after amplified, at various power levels. RF transmission system 400 includes at least one power amplifier 412, at least one power supply 414, an antenna matching unit 420, and an antenna 430. System 400 may also include one or more combiners 416. In such a RF transmission system, it is important for power management controller 210 to monitor the characteristics of system 400, including the power draw for individual signals, to dynamically optimize the number and characteristics of the signals to be supported while not exceeding the allowable power limits. Moreover, for reactive transmitters such as those employed in electronic warfare systems, the transmitter amplifier can be overloaded during high traffic, dense input signal events, to the extent that radio link system is impaired: distortion in excess of specified limits or power source overload/shutdown.

In an RF, microwave transmitter, a lower amplitude input waveform will be amplified to a higher power level for inputting to antenna 430 such that the RF energy can be radiated. Detection and measurement circuitries 220 (shown in FIG. 2) persistently monitors and measure input signals 440 over a predetermined time period, either synchronously or asynchronously, and categorizes input signals based on their amplitudes, modulations, duty cycles, phases, and so on. Those data measured by detection and measurement circuitries 220 are input RF waveforms measurements 225 and are sent to power management controller 210. Power management controller 210 classifies the input waveform against available power amplifier bias classes to determine optimal amplifier biasing options for the type of input waveform applied. Optimal classes of operation include linearity, power added efficiency, duty cycle, etc. At the same time, detection and measurement circuitries 220 monitors the capability of input powers of power supplies 414 that is available to power amplifiers 412 and ensuring an overload situation does not happen by limiting some aspect of the transmit signal. The input power data measured by detection and measurement circuitries 220 are input power conditions measurements.

It is noted that although FIG. 4 only shows measurements regarding input power conditions 229 and input RF waveforms quality 225 that are detected and measured by detection and measurement circuitries 220, power management controller 210 also process all other measurements shown in FIG. 3, such as the power draw amount by the power amplifier 221, output load quality 227, and transmitter thermal conditions 223 to dynamically adjust the input power or the output power to keep the output power within the desired range while ensuring that the input power draw does not exceed the available power, as described in FIG. 3.

Input RF waveforms measurements 225 and input power conditions measurements 229 are sent to power management controller 210 for processing. Further, power management controller 210 may store a priority list 219 of input signals in memory 250. The priority list 219 prioritizes the importance and urgency levels of input signals 440.

For example, as the number of input signals 440 increases, and/or if certain detected signals match high priority signals stored in priority list 219, power management controller 210 may automatically adjust the operating points of power ampliﬁers 412 to optimally amplify the multiple input signals so that they can be transmitted with sufficient transmitting output power. Alternatively, power management controller 210 may limit power supply currents from power supplies 414 to both protect power ampliﬁers 412 and prevent the RF transmission system 400 from being overloaded. Power management controller 210 may also limit input signals to selectively transmit higher-priority signals within the capabilities of power amplifiers 412.

Normally, the broadcast traffic can be high or low based on the time of the day. When the broadcast traffic is high, more signal carriers are required to transmit signals, while when the broadcast traffic is low, less signal carriers are needed. Therefore, power management controller 210 may also determine what signals to be transmitted in a high traffic time and a low traffic time. For example, power management controller 210 may control transmission system 400 to transmit only signals with higher priorities at a high broadcast traffic time, and save signals with lower priorities to be transmitted at a low broadcast traffic time.

Furthermore, power management controller 210 may control the elements of transmission system 100 to keep the output power within a desired range while ensuring that the input power draw does not exceed the available power by adapting at least one of a linearity and efficiency characteristics of the at least one power amplifier. In this case, power management controller 210 may change at least one of a bias voltage and a supply voltage of the at least one power amplifier to affect the at least one of the linearity and efficiency of the at least one power amplifier.

In some embodiments, power management controller 210 may determine linearity requirements of the at least one power amplifier based on priority list 210 of the multiple input signals 440 stored in memory 250 and a measurement of a quality of at least one signal of the multiple input signals. Based on the quality of the at least one signal of the multiple input signals, power management controller 210 may adjust the relative transmit power of the multiple input signals so that the signals with higher-priorities can be transmitted with more transmit power than those with lower-priorities.

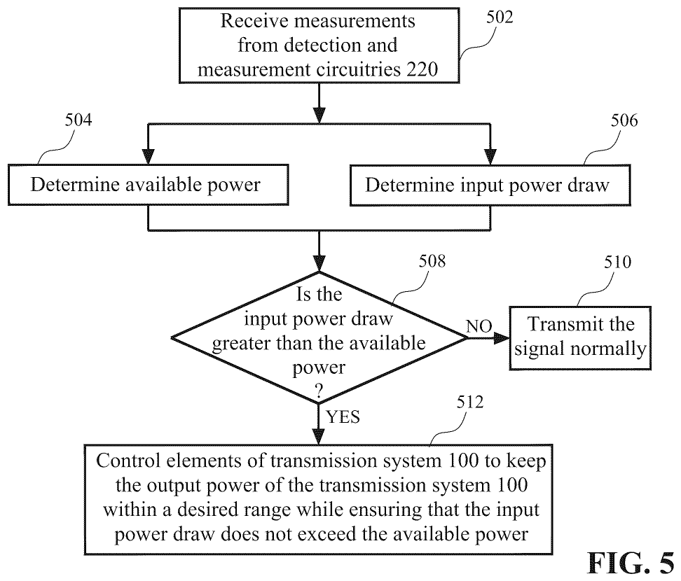

FIG. 5 is a flowchart 500 of a method for managing output power of a RF transmission system using power management and control system in accordance with the disclosed embodiments. Flowchart 500 may refer to FIGS. 3 and 4 for illustrative purposes.

Step 502 executes by receiving measurements from multiple detection and measurement circuitries. As described in FIG. 3, the detection and measurement circuitries may detect and measures data regarding the amount of power draw of at least one power amplifier 221, transmitter thermal conditions 223, RF input signal waveform conditions 225, output load quality 227, and input power conditions 229.

Step 504 executes by determining available power that transmission system 100 is allowed to draw based on the measurements received at step 502. Stepp 506 also executes by determining an input power drawn that transmission system 100 of FIG. 3 or 400 of FIG. 4.

Next, step 508 executes by determining if the input power draw is greater than the available power. If the answer is No, which means there is sufficient power from a power source for transmission system 100 or 400 to transmit input signal 140 or multiple signals 440, transmission system 100 or 400 will transmit the signal 140 or signals 440 normally, as shown in step 510. However, if the answer is Yes, which means there is not sufficient power to transmit signal 140 or signals 440. Flowchart 500 goes to step 508.

Step 508 then executes by controlling the elements of transmission system 100 to keep the output power of transmission system 100 within a desired range while ensuring that the input power drawn of transmission system 100 does not exceed the available power.

As described in scenarios 1-3 of FIG. 3 and the embodiments of FIG. 4, the methods to keep the output power of transmission system 100 or 400 within a desired range while ensuring the input power draw of transmission system 100 or 400 not exceeding the available power may include by at least one or more the followings, but not limited thereto: reducing a signal level or signal levels of at least one input signal to at least one power amplifier, attenuating the at least one input signal within the at least one power amplifier, reducing a gain of the at least one power amplifier, and reducing a supply voltage of the at least one power amplifier. Alternative methods may adapt at least one of a linearity and efficiency characteristics of the at least one power amplifier, change at least one of a bias voltage and a supply voltage of the at least one power amplifier to affect at least one of the linearity and the efficiency of the at least one power amplifier, dynamically determines the input power draw of the transmission system using the measurements within transmission system 100 or 400, or based on transmitter characterization to determine the input power draw from the power supply. Another alternative method may include reducing a maximum power that can be drawn from the external supply, based on at least one temperature value measured by detection and measurement circuitries 220, as the at least one temperature increases. Details of these methods can be referred to FIGS. 3 and 4, and thus are omitted here for simplification.

Further, power management controller 210 may comprise analog circuits, or simple digital processing circuit, or a processor. In the latter, controller 210 further includes a memory that stores medium-readable instructions that, when executes, will cause the processor to execute functions such as measuring data, calculating data, comparing data, analyzing data, etc.

While the present disclosure has been particularly described, the power management and control system 200 in accordance with the disclosed embodiments can dynamically and automatically manage and control the input power or output power of a RF transmission system based on various parameters. These various parameters include, but not limited to, the quality of input RF signals, the quality of loads connected to the transmitter, the quality and availability of the input power supply, and the thermal condition of the transmitter. By referring to the quality data, power management and control system 200 is able to limit the power draw from a limited power source, to reduce the amplifier power, to reduce the output power, or to limit the maximum number of signals to be transmitted so as to prevent the transmitter from damaging due to an overload or a sudden shutdown due to insufficient power supply.

While the present disclosure has been particularly described, in conjunction with specific preferred embodiments, it is evident that many alternatives, modifications and variations will be apparent to those skilled in the art in light of the foregoing description. It is therefore contemplated that the appended claims will embrace any such alternatives, modifications and variations as falling within the true scope and spirit of the present disclosure.

What is claimed is:

1. A system for managing the transmission power of a RF (Radio Frequency) transmission system including a transmitter, wherein the transmitter includes at least one power amplifier, and wherein the transmitter draws a power from an external power supply that has a limited power capacity, the system comprising:
a plurality of detection and measurement circuitries coupled to the transmitter to determine parameters relative to the transmitter, wherein the parameters comprise measurements within the transmitter, a quality measurement of an input power draw of the transmitter from the external power supply, and a quantity measurement of the input power available to the transmitter from the external power supply; and
a power management controller configured to receive and process the parameters detected by the plurality of detection and measurement circuitries and to manage and control an output power of the transmitter based the parameters, wherein the power management controller is configured to
determine an available input power that the transmitter is allowed to draw based on the measurements of the detection and measurement circuitries, wherein the available input power is either fixed or configurable;
dynamically determine an input power draw of the transmitter from the power supply; and
control elements of the transmitter to keep the output power within a desired range while ensuring that the input power draw of the transmitter does not exceed the available power from the external power supply.

2. The system of claim 1, further comprising an input device for receiving user inputs and a memory for storing at least one available power threshold for the transmitter, wherein the user inputs include at least one adjustment of the available power that is supplied to the transmitter and the output power of the transmitter, and wherein the power management controller controls the element of the transmitter to ensuring the input power the transmitter draws does not exceed the available power based on at least one available power threshold stored in the memory.

3. The system of claim 1, wherein the power management controller determines the available input power that is available to be supplied to the transmitter based on at least one of: reading the available power threshold stored in the memory that indicates the available power, detecting an analog signal that is mapped to indicate the available power, and detecting a digital signal that indicates the available power.

4. The system of claim 1, wherein the power management controller dynamically determines the input power draw of the transmitter using the measurements within the transmitter, or based on transmitter characterization to determine the input power draw from the power supply.

5. The system of claim 1, wherein the power management controller is configured to control the elements of the transmitter to keep the output power within the desired range while ensuring that the input power draw does not exceed the available power by reducing the output power of the transmitter.

6. The system of claim 5, wherein the power management controller is configured to reduce the output power of the transmitter by at least one or more the followings: reducing a level of a signal input to the at least one power amplifier, attenuating the signal within the at least one power amplifier, reducing a gain of the at least one power amplifier, and reducing a supply voltage of the at least one amplifier.

7. The system of claim 1, wherein the power management control is further configured to control the elements of the transmitter to keep the output power within the desired range while ensuring that the input power draw does not exceed the available power by adapting at least one of a linearity and efficiency characteristics of the at least one power amplifier.

8. The system of claim 7, wherein the power management controller is configured to change at least one of a bias voltage and the supply voltage of the at least one power amplifier to affect at least one of the linearity and the efficiency characteristics of the at least one power amplifier.

9. The system of claim 2, wherein the external power supply is communicatively coupled to the transmitter, and wherein the power management controller is configured to determine the input power that is available to be supplied to the transmitter based on at least one of a message received from the external power supply and the user inputs.

10. The system of claim 1, wherein the system further comprises an automatic level control (ALC) mechanism to limit output power levels of the transmitter, and wherein the power management controller is used in conjunction with the ALC mechanism to control the elements of the transmitter to keep the output power within the desired range while ensuring that the input power draw does not exceed the available power.

11. The system of claim 1, wherein the parameters includes at least one temperature value measured within the transmission system, and the power management controller is further configured to control the elements of the transmitter to keep the output power within the desired range while ensuring that the input power draw does not exceed the available power by using the at least one temperature value in the determination of the power available from the power supply, whereby a maximum power that can be drawn from the power supply is reduced as the at least one temperature increases.

12. A system for managing the transmission power of a RF (Radio Frequency) transmission system, wherein the RF transmission system comprises a transmitter to transmit multiple input signals, wherein the transmitter includes at least one power amplifier for amplifying the multiple input signals before being transmitted by the transmitter, and wherein the at least one power amplifiers draw power from a power supply that has a limited power capacity, the system comprising:
a plurality of detection and measurement circuitries coupled to the transmitter to determine parameters relative to the transmitter, wherein the parameters comprise measurements within the transmitter, a quality measurement of an input power draw of the transmitter from the external power supply, and a quantity measurement of the input power available to the transmitter from the external power supply; and
a power management controller configured to process the parameters detected by the plurality of detection and measurement circuitries and to manage and control the transmit power, wherein the power management controller is configured to
determine an available input power that the transmitter is allowed to draw based on the measurements of the detection and measurement circuitries, wherein the available input power is either fixed or configurable;
dynamically determine the input power draw for the transmitter based on the measurements within the transmitter and power levels of the multiple signals; and
control elements of the transmitter to keep the output power of the transmitter within a desired range while ensuring that the input power draw does not exceed the available power.

13. The system of claim 12, wherein the power management controller is configured to control the elements of the transmitter to keep the output power within the desired range while ensuring that the input power draw does not exceed the available power by adapting at least one of a linearity and an efficiency characteristics of the at least one power amplifier.

14. The system of claim 13, wherein the power management controller is further configured to change at least one of a bias voltage and a supply voltage of the at least one power amplifier to affect the at least one of the linearity and efficiency of the at least one power amplifier.

15. The system of claim 14, wherein the system further comprises a memory for storing a priority list of the multiple signals, and wherein the power management controller is configured to determine linearity requirements of the at least one power amplifier based on the priority list of the multiple input signals and a measurement of a quality of at least one signal of the multiple input signals.

16. The system of claim 15, wherein the parameters determined by measurement of the at least one quality of the at least one input signals are used to adjust the relative transmit power of the multiple input signals.

17. The system of claim 12, wherein the external power supply is communicatively coupled to the transmitter, and wherein the power management controller is configured to determine the available input power that is available to be supplied to the transmitter based on at least one of a message received from the external power supply.

18. A method for managing and controlling a transmit power of an RF transmission system, wherein the RF transmission system includes a transmitter to transmit at least one signal, wherein the transmitter includes at least one power amplifier for amplifying at least one input signal to the at least one signal, and an external power supply that has a limited power capacity, the method comprising:
measuring various parameters relative to the transmitter, wherein the parameters comprise measurements within the transmitter, a quality measurement of an input power draw of the transmitter from the external power supply, and a quantity measurement of the input power available to the transmitter from the external power supply;
determining an available input power that the transmitter is allowed to draw from the external power supply based on the measurements of the detection and measurement circuitries, wherein the available input power is either fixed or configurable;
dynamically determining the input power draw for the transmitter based on the measurements within the transmitter; and
controlling elements of the transmitter to keep the output power of the transmitter within the desired range while ensuring that the input power draw does not exceed the available power.

19. The method of claim 18, further comprising reducing the output power of the transmitter by at least one or more of the following: reducing the power level of the at least one input signal, attenuating the input signal within the at least one power amplifier, reducing a gain of the at least one power amplifier, and reducing a supply voltage of the at least one power amplifier.

20. The method of claim 18, further comprising controlling the elements of the transmitter to keep output power within the desired range while ensuring that the input power draw does not exceed the available power by adapting at least one of a linearity and an efficiency characteristic of the at least one power amplifier.
